(19) United States
(12) Patent Application Publication
(10) Pub. No.: US 2018/0032271 A1
(43) Pub. Date: Feb. 1, 2018

(54) SEMICONDUCTOR MEMORY DEVICE AND OPERATING METHOD THEREOF

(71) Applicant: SK hynix Inc., Gyeonggi-do (KR)

(72) Inventors: Ji Hyun SEO, Seoul (KR); Eun Mee KWON, Gyeonggi-do (KR); Sung Yong CHUNG, Gyeonggi-do (KR)

(21) Appl. No.: 15/398,844

(22) Filed: Jan. 5, 2017

(30) Foreign Application Priority Data
Jul. 28, 2016 (KR) 10-2016-0096333

(51) Int. Cl. G06F 3/06; G11C 16/10

(52) U.S. Cl. CPC G06F 3/0619; G06F 3/064; G06F 3/0659; G06F 3/0665; G06F 3/0679; G11C 16/10

(57) ABSTRACT

A semiconductor memory device includes a memory cell array including a plurality of pages, peripheral circuits programming memory cells included in a selected page of the plurality of pages into a plurality of program states, and a control logic controlling the peripheral circuits to perform a program operation, wherein the control logic controls the peripheral circuits so that a first variable pass voltage applied to a page adjacent to the selected page is different from a pass voltage applied to remaining unselected pages during a program operation for a first set program state having a low threshold voltage distribution, among the plurality of program states.

### CROSS-REFERENCE TO RELATED APPLICATION

The present application claims priority under 35 U.S.C. §119(a) to Korean patent application number 10-2016-0096333, filed on Jul. 28, 2016, the disclosure of which is incorporated herein by reference in its entirety.

### BACKGROUND

### Field of Invention

Various embodiments of the invention relate to a semiconductor memory device and an operating method thereof.

### Description of Related Art

Semiconductor memory devices may be classified into volatile memory devices and non-volatile memory devices.

Non-volatile memory devices operate at relatively low write and read speeds than volatile memory devices, but they retain the stored data regardless of power on/off conditions. Therefore, non-volatile memory devices are used to store data which need to be maintained even in the absence of power supply. Examples of non-volatile memory include read only memory (ROM), mask ROM (MROM), programmable ROM (PROM), erasable programmable ROM (EPROM), electrically erasable and programmable ROM (EEPROM), flash memory, Phase-change random access memory (PRAM), magnetic RAM (MRAM), resistive RAM (RRAM) and ferroelectric RAM (FRAM). Flash memories are used widely and may be classified into NOR- or NAND-type memories.

Flash memories enjoy advantages of both RAM and ROM devices. For example, flash memories may be freely programmed and erased similar to a RAM. Also, similar to a ROM, flash memories may retain the stored data even when they are not powered. Flash memories have been widely used as the storage media of portable electronic devices such as mobile phones, digital cameras, personal digital assistants (PDAs), and MP3 players.

Flash memory devices may be classified into two-dimensional semiconductor devices in which strings are formed in a horizontal direction to a semiconductor device and three-dimensional semiconductor devices in which strings are formed in a vertical direction to a semiconductor device.

A three-dimensional semiconductor device generally overcome limitations of integration of two-dimensional semiconductor devices. A three-dimensional semiconductor device may include a plurality of strings arranged in a vertical direction to a semiconductor substrate. Each of the plurality of strings may include a drain selection transistor, memory cells and a source selection transistor connected in series between a bit line and a source line.

### SUMMARY

Various embodiments are directed to a semiconductor memory device capable of improving a threshold voltage distribution of memory cells during a program operation, and an operating method thereof.

According to an embodiment, a semiconductor memory device may include a memory cell array including a plurality of pages, peripheral circuits programming memory cells included in a selected page of the plurality of pages into a plurality of program states, and a control logic controlling the peripheral circuits to perform a program operation, wherein the control logic controls the peripheral circuits so that a first variable pass voltage applied to a page adjacent to the selected page is different from a pass voltage applied to remaining unselected pages during a program operation for a first set program state having a low threshold voltage distribution, among the plurality of program states.

According to an embodiment, a semiconductor memory device may include a memory cell array including a plurality of pages, peripheral circuits programming memory cells included in a selected page, among the plurality of pages, into a plurality of program states, and a control logic controlling the peripheral circuit to perform a program operation, wherein the control logic controls the peripheral circuits so that a first or second variable pass voltage applied to a page adjacent to the selected page is different from a pass voltage applied to remaining unselected pages during a program operation for a first set program state having a low threshold voltage distribution, among the plurality of program states, and a program operation for a second set program state having a high threshold voltage distribution, among the plurality of program states.

According to an embodiment, a method of operating a semiconductor memory device may include setting a first variable pass voltage to be applied to pages adjacent to a selected page of a plurality of pages in a first set program state having a low threshold voltage distribution, among a plurality of program states, performing a first program operation for the first set program state by applying a program voltage to the selected page, applying the first variable pass voltage to the pages adjacent to the selected page, and applying a pass voltage to remaining pages, and performing a second program operation for a next program state having a higher threshold voltage distribution than the first set program state by applying the program voltage to the selected page and applying the pass voltage to unselected pages.

### BRIEF DESCRIPTION OF THE DRAWINGS

The above and other features and advantages of the present invention will become more apparent to those skilled in the art to which the present invention belongs by the following detailed description with reference to the attached drawings in which:

FIG. 1 is a block diagram Illustrating a semiconductor memory device according to an embodiment of the present invention;

FIG. 2 is a block diagram illustrating an embodiment of a memory cell array shown in FIG. 1;

FIG. 3 is a three-dimensional view illustrating a memory string included in a memory block shown in FIG. 1;

FIG. 4 is a cross-sectional view illustrating a memory string shown in FIG. 3;

FIG. 5 is a cross-sectional view illustrating another structure of a memory string shown in FIG. 3;

FIG. 6 is a circuit diagram Illustrating a memory block shown in FIG. 1;

FIG. 7 is a flowchart illustrating an operation of a semiconductor memory device according to an embodiment of the present invention;

FIG. 8 is a threshold voltage distribution chart Illustrating operations of a semiconductor memory device according to an embodiment of the present invention;

FIG. 9 is a waveform view of word line voltages for illustrating operations of a semiconductor memory device according to an embodiment of the present invention;

FIG. 10 is a block diagram Illustrating a memory system including a semiconductor memory device shown in FIG. 1, according to an embodiment of the present invention;

FIG. 11 is a block diagram illustrating an application example of a memory system shown in FIG. 10, according to an embodiment of the present invention; and

FIG. 12 is a block diagram illustrating a computing system including a memory system described with reference to FIG. 11, according to an embodiment of the present invention.

### DETAILED DESCRIPTION

Hereinafter, various exemplary embodiments will be described in detail with reference to the accompanying drawings. The present disclosure, however, may be embodied in various different forms, and should not be construed as being limited to the illustrated embodiments herein. Rather, these embodiments are provided as examples so that this disclosure will be thorough and complete, and will fully convey the various aspects and features of the present invention to those skilled in the art.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to more clearly illustrate the various elements of the embodiments. For example, in the drawings, the size of elements and the intervals between elements may be exaggerated compared to actual sizes and intervals for convenience of illustration.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

Spatially relative terms, such as “under,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in manufacturing, use or operation in addition to the orientation depicted in the figures. For example, if the device in the figures is turned over, elements described as “below” or “under” other elements or features would then be “above” the other elements or features. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, singular forms are intended to include the plural forms as well, unless the context clearly indicates otherwise. It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs in view of the present disclosure. It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, an element (also referred to as a feature) described in connection with one embodiment may be used singly or in combination with other elements of another embodiment, unless specifically indicated otherwise.

Hereinafter, the various embodiments of the present invention will be described in detail with reference to the attached drawings.

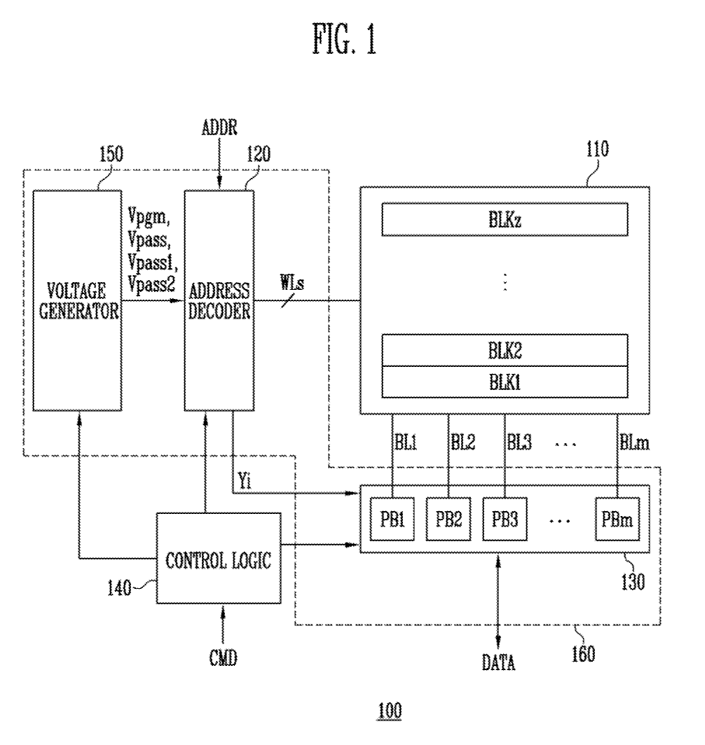

Referring now to FIG. 1, a semiconductor memory device 100 is provided, according to an embodiment of the present invention.

Referring to FIG. 1, the semiconductor memory device 100 may include a memory cell array 110, an address decoder 120, a read and write circuit 130, a control logic 140, and a voltage generator 150.

The memory cell array 110 may include a plurality of memory blocks BLK1 to BLKz. The memory blocks BLK1 to BLKz may be coupled to the address decoder 120 through word lines WLs. The memory blocks BLK1 to BLKz may be coupled to the read and write circuit 130 through bit lines BL1 to BLm. Each of the memory blocks BLK1 to BLKz may include a plurality of memory cells. According to an embodiment, the plurality of memory cells may be non-volatile memory cells. Memory cells coupled to a single word line, among the plurality of memory cells, may be defined as a single page. In other words, the memory cell array 110 may include a plurality of pages.

Each of the memory blocks BLK1 to BLKz of the memory cell array 110 may include a plurality of cell strings. Each of the plurality of cell strings may include a drain selection transistor, a plurality of memory cells, and a source selection transistor which are coupled in series between a corresponding bit line and a common source line. The memory cell array 110 will be described below in detail.

The address decoder 120, the read and write circuit 130, and the voltage generator 150 may operate as peripheral circuits for driving the memory cell array 110.

The address decoder 120 may be coupled to the memory cell array 110 through the word lines WLs. The address decoder 120 may operate in response to control of the control logic 140. The address decoder 120 may receive an address ADDR through an input/output buffer (not illustrated) in the semiconductor memory device 100.

The address decoder 120 may transfer a program voltage Vpgm, a pass voltage Vpass, and first and second variable pass voltages Vpass1 and Vpass2 generated by the voltage generator 150 to the word lines WLs of the memory cell array 110 according to the received address ADDR during a program operation.

For example, during the program operation, the address decoder 120 may apply the program voltage Vpgm to a selected one among the word lines WLs, apply the first variable pass voltage Vpass1 or the second variable pass voltage Vpass2 to word lines adjacent to the selected word line, and apply the pass voltage Vpass to remaining unselected word lines.

The address decoder 120 may decode a column address of the received address ADDR. The address decoder 120 may transfer the decoded column address Yi to the read and write circuit 130.

The address ADDR received during the program operation may include a block address, a row address and a column address. The address decoder 120 may select one memory block and one word line according to the block address and the row address. The column address Yi may be decoded by the address decoder 120 and provided to the read and write circuit 130.

The address decoder 120 may include a block decoder, a row decoder, column decoder and an address buffer.

The read and write circuit 130 may include a plurality of page buffers PB1 to PBm. The page buffers PB1 to PBm may be coupled to the memory cell array 110 through the bit lines BL1 to BLm, respectively. Each of the page buffers PB1 to PBm may control the potential of each of the bit lines BL1 to BLm corresponding to data DATA to be programmed during a program operation.

The read and write circuit 130 may operate in response to control of the control logic 140.

According to an embodiment, the read and write circuit 130 may include a column selection circuit (not shown), which may include a plurality of page buffers or page registers.

The control logic 140 may control the address decoder 120, the read and write circuit 130, and the voltage generator 150. The control logic 140 may receive a command CMD through an input/output buffer (not illustrated) of the semiconductor memory device 100. The control logic 140 may control the general operations of the semiconductor memory device 100 in response to the command CMD.

The control logic 140 may control the address decoder 120, the read and write circuit 130, and the voltage generator 150 so that a plurality of memory cells included in a selected page may have a plurality of program states during a program operation. The program operation may be performed by programming the plurality of memory cells in a sequential manner starting from a program state having a low threshold voltage distribution and gradually progressing to a program state having a high threshold voltage distribution.

The control logic 140 may control the address decoder 120 and the voltage generator 150 so that the first variable pass voltage Vpass1 which is higher than the pass voltage Vpass may be applied to pages adjacent to the selected page during a program operation for first set program states having a low threshold voltage distribution. The first variable pass voltage Vpass1 may be higher than the pass voltage Vpass by a first voltage adjustment value ΔV1. The first voltage adjustment value ΔV1 may vary depending on an address of the selected page. For example, as a channel width of the memory cells included in the selected page becomes narrower, the first voltage adjustment value ΔV1 may decrease. As the channel width of the memory cells included in the selected page becomes wider, the first voltage adjustment value ΔV1 may increase.

In addition, the control logic 140 may control the address decoder 120 and the voltage generator 150 so that the second variable pass voltage Vpass2 which is lower than the pass voltage Vpass may be applied to pages adjacent to the selected page during a program operation for second set program states having a high threshold voltage distribution. The second variable pass voltage Vpass2 may be lower than the pass voltage Vpass by a second voltage adjustment value ΔV2. The second voltage adjustment value ΔV2 may vary depending on the address of the selected page. The second voltage adjustment value ΔV2 decreases as the channel width of the memory cells included in a selected page becomes narrower. As the channel width of the memory cells included in a selected page becomes wider, the second voltage adjustment value ΔV2 increases.

The first set program states and the second set program states may have one or more program states, respectively.

The voltage generator 150 may generate the program voltage Vpgm, the pass voltage Vpass, the first variable pass voltage Vpass1 and the second variable pass voltage Vpass2 in response to control of the control logic 140 during a program operation and a read operation. The first variable pass voltage Vpass1 may be higher than the pass voltage Vpass by the first voltage adjustment value ΔV1, and the second variable pass voltage Vpass2 may be lower than the pass voltage Vpass by the second voltage adjustment value ΔV2.

FIG. 2 is a block diagram Illustrating an embodiment of the memory cell array 110 shown in FIG. 1.

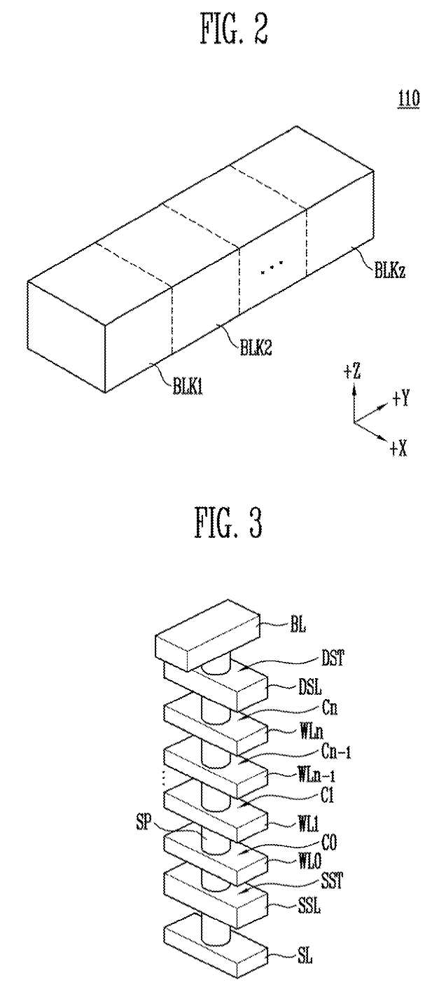

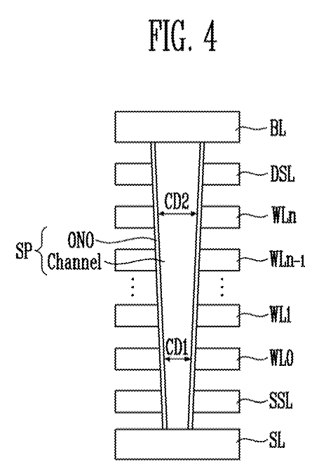

Referring to FIG. 2, the memory cell array 110 may include the plurality of memory blocks BLK1 to BLKz. Each of the memory blocks BLK1 to BLKz may have a three-dimensional structure. Each memory block may include a plurality of memory cells that are stacked over a substrate. The plurality of memory cells may be arranged in +X direction, +Y direction and +Z direction. The structure of each memory block will be described in more detail with reference to FIGS. 3, 4, and 5.

FIG. 3 is a three-dimensional view illustrating a memory string included in a memory block shown in FIG. 1.

Referring to FIG. 3, a source line SL may be formed over a semiconductor substrate (not shown). A vertical channel layer SP may be formed over the source line SL. A top portion of the vertical channel layer SP may be coupled to the bit line BL. For example, the vertical channel layer SP may include polysilicon. A plurality of conductive layers (SSL, WL0 to WLn, and DSL) may surround the vertical channel layer SP at different heights of the vertical channel layer SP. A multilayer film (not illustrated) including a charge storage layer may be formed on a surface of the vertical channel layer SP. The multilayer film may also be located between the vertical channel layer SP and the conductive layers (SSL, WL0 to WLn, and DSL). The multilayer film may have an ONO structure in which an oxide layer, a nitride layer, and an oxide layer are sequentially stacked.

The lowermost conductive layer may be a source selection line SSL, and the uppermost conductive layer may be a drain selection line DSL. The conductive layers between the selection lines SSL and DSL may be word lines WL0 to WLn. In other words, the conductive layers (SSL, WL0 to WLn, and DSL) may be formed in a plurality of layers over the semiconductor substrate, and the vertical channel layer SP passing through the conductive layers (SSL, WL0 to WLn, and DSL) may be connected in a vertical direction between the bit line BL and the source line SL formed on the semiconductor substrate.

A drain selection transistor DST may be formed at a portion where the uppermost conductive layer DSL surrounds the vertical channel layer SP, and a source selection transistor SST may be formed at a portion where the lowermost conductive layer SSL surrounds the vertical channel layer SP. Memory cells MC0 to MCn may be formed at portions where intermediate conductive layers (WL0 to WLn) surround the vertical channel layer SP.

As a result, the memory string having the above-described structure may include the source selection transistor SST, the memory cells MC0 to MCn and the drain selection transistor DST that are coupled in a vertical direction to the substrate between the source line SL and the bit line BL. The source selection transistor SST may electrically couple the memory cells MC0 to MCn to the source line SL in response to a source control voltage applied to the source selection line SSL. The drain selection transistor DST may electrically connect the memory cells MC0 to MCn to the bit line BL in response to a drain control voltage applied to the drain selection line DSL.

FIG. 4 is a cross-sectional view of the memory string shown in FIG. 3.

Referring to FIG. 4, the source line SL may be formed over the semiconductor substrate. A vertical channel Channel may be formed on the source line SL. A top portion of the vertical channel Channel may be coupled to the bit line BL. The vertical channel Channel may include polysilicon. A plurality of conductive layers (SSL, WL0 to WLn, and DSL) may surround the vertical channel Channel at different heights of the vertical channel Channel. The conductive layers (SSL, WL0 to WLn, and DSL) may be spaced apart at a regular interval along the direction of the channel Channel. The interspace between two consecutive conductive layers may include an insulating layer. Also, the interspace between the source select line SSL and the source layer SL and the interspace between the drain select line DSL and the bit line BL may each include an insulating layer.

A memory layer ONO including a charge storage layer may be formed on a surface of the vertical channel Channel. The memory layer ONO may be located between the vertical channel Channel and the conductive layers (SSL, WL0 to WLn, and DSL). The vertical channel Channel and the memory layer ONO may correspond to the vertical channel layer SP as shown in FIG. 3.

The lowermost conductive layer may be the source selection line SSL, and the uppermost conductive layer may be the drain selection line DSL. The conductive layers between the selection lines (DSL and SSL) may be the word lines WL0 to WLn.

A source selection transistor may be formed at a portion where the source selection line SSL surrounds the vertical channel Channel. A drain selection transistor may be formed at a portion where the uppermost conductive layer DSL surrounds the vertical channel Channel. Memory cells may be formed at portions where the word lines WL0 to WLn surround the vertical channel Channel.

The vertical channel Channel of the memory string may have an upper width that is greater than a lower width. For example, a channel width CD1 of a memory cell corresponding to the conductive layer WL0 may be smaller than a channel width CD2 of a memory cell corresponding to the conductive layer WLn. A channel width of a memory cell may decrease in a direction from the uppermost surface of the channel toward the lowermost surface of the channel. Hence, in a direction from the bit line BL and the drain select transistor DSL toward the source selection transistor SSL and the source layer SL the channel width is gradually decreasing.

FIG. 5 is a cross-sectional view illustrating another structure of the memory string shown in FIG. 3.

Referring to FIG. 5, a common source line SL may be formed over the semiconductor substrate (not shown). The vertical channel Channel may be formed over the common source line SL. A top portion of the vertical channel Channel may be coupled to the bit line BL. The vertical channel Channel may include polysilicon. A plurality of conductive layers (SSL, WL0 to WLn, and DSL) may surround the vertical channel Channel at different heights of the vertical channel Channel. The conductive layers (SSL, WL0 to WLn, and DSL) may be spaced apart at a regular interval along the direction of the channel Channel. The interspace between two consecutive conductive layers may include an insulating layer. Also, the Interspace between the source select line SSL and the source layer SL and the interspace between the drain select line DSL and the bit line BL may each include an insulating layer.

The memory layer ONO including a charge storage layer may be formed on a surface of the vertical channel Channel. The memory layer ONO may also be located between the vertical channel Channel and the conductive layers (SSL, WL0 to WLn, and DSL). The vertical channel Channel and the memory layer ONO may correspond to the vertical channel layer SP as shown in FIG. 3.

The lowermost conductive layer may be the source selection line SSL, and the uppermost conductive layer may be the drain selection line DSL. The conductive layers between the selection lines DSL and SSL may be the word lines WL0 to WLn.

A source selection transistor may be formed at a portion where the source selection line SSL surrounds the vertical channel Channel. A drain selection transistor may be formed at a portion where the uppermost conductive layer DSL surrounds the vertical channel Channel. Memory cells may be formed at portions where the word lines WL0 to WLn surround the vertical channel Channel.

The above-described memory string of FIG. 5 may be divided into a first cell portion and a second cell portion. The second cell portion may be stacked on top of the first cell portion. A channel width CD4 of the uppermost memory cell of the first cell portion may be different from a channel width CD3 of the lowermost memory cell of the second cell portion. More specifically, the channel width CD4 of the uppermost memory cell of the first cell portion may be greater than the channel width CD3 of the lowermost memory cell of the second cell portion.

In addition, a channel width of a memory cell of the first cell portion may gradually decrease toward the source selection transistor and the semiconductor substrate, and a channel width of a memory cell of the second cell portion may gradually decrease toward the first cell portion.

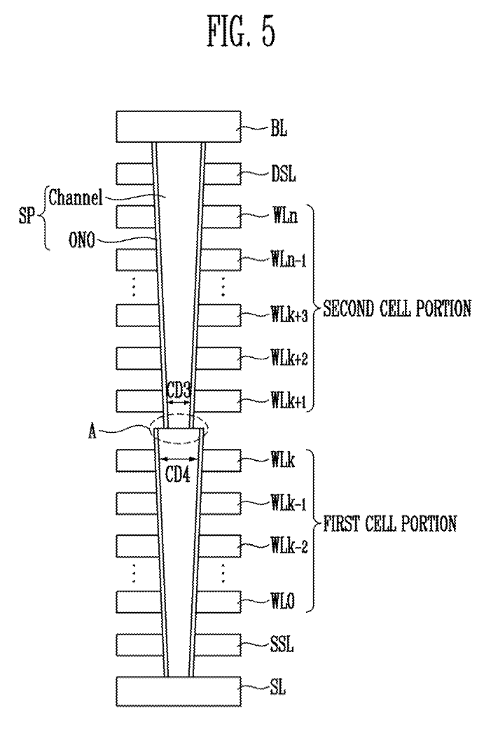

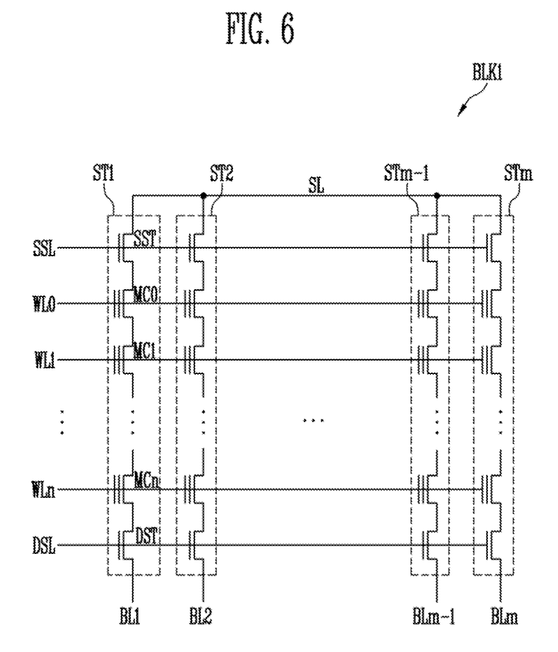

FIG. 6 is a circuit diagram Illustrating an exemplary configuration of a memory block shown in FIG. 1, according to an embodiment of the present invention.

Referring to FIG. 6, the memory block BLK1 may include a plurality of cell strings ST1 to STm. Each of the plurality of cell strings ST1 to STm may be coupled to a corresponding bit line among a plurality of bit lines BL1 to BLm, respectively.

Each of the plurality of memory strings ST1 to STm may include the source selection transistor SST, the plurality of memory cells MC0 to MCn coupled in series, and the drain selection transistor DST. The gate of each source selection transistor SST in the plurality of strings ST1 to STm may be coupled to the common source selection line SSL. The gates of the memory cells MC0 to MCn may be coupled to the word lines WL0 to WLn, respectively. The gate of each drain selection transistor DST in the plurality of strings ST1 to STm may be coupled to the common drain selection line DSL. The common source line SL may be coupled to a source side of each of the source selection transistors SST in the plurality of strings ST1 to STm. Each of the bit lines BL1 to BLm may be coupled to a drain side of the drain selection transistor DST corresponding thereto. The word lines WL as described with reference to FIG. 1 may include the source selection line SSL, the word lines WL0 to WLn and the drain selection line DSL. The source selection line SSL, the word lines WL0 to WLn and the drain selection line DSL may be driven by the address decoder 120.

In addition, in the memory block BLK1, memory cells coupled to the same word line may be defined as a single page. For example, the memory cells MC0 in the plurality of strings ST1 to STm which are coupled to the same word line WL0 may be defined as a single page.

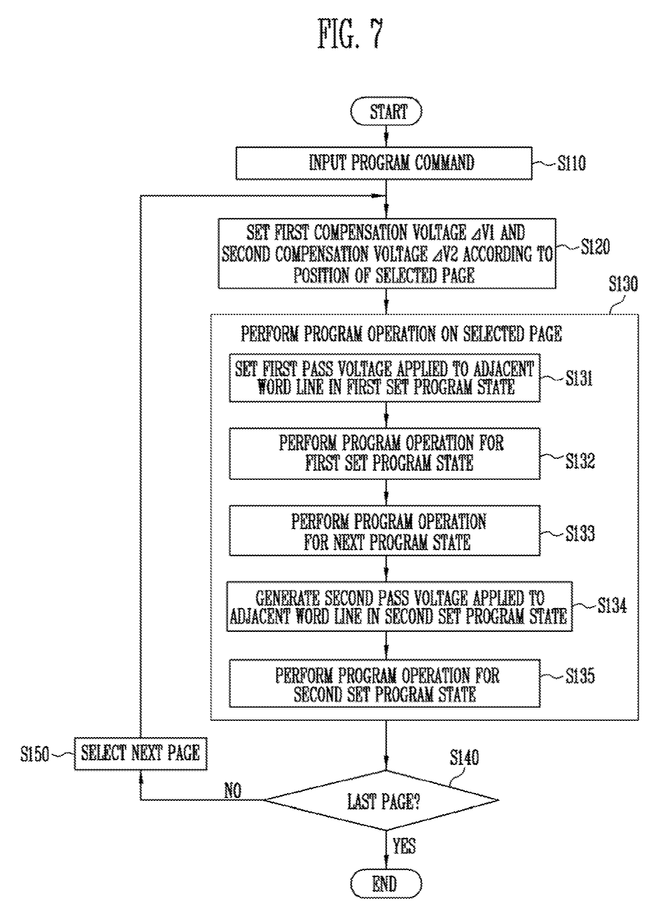

FIG. 7 is a flowchart illustrating operations of a semiconductor memory device, according to an embodiment of the present invention.

FIG. 8 is a threshold voltage distribution chart illustrating operations of a semiconductor memory device according to an embodiment of the present invention.

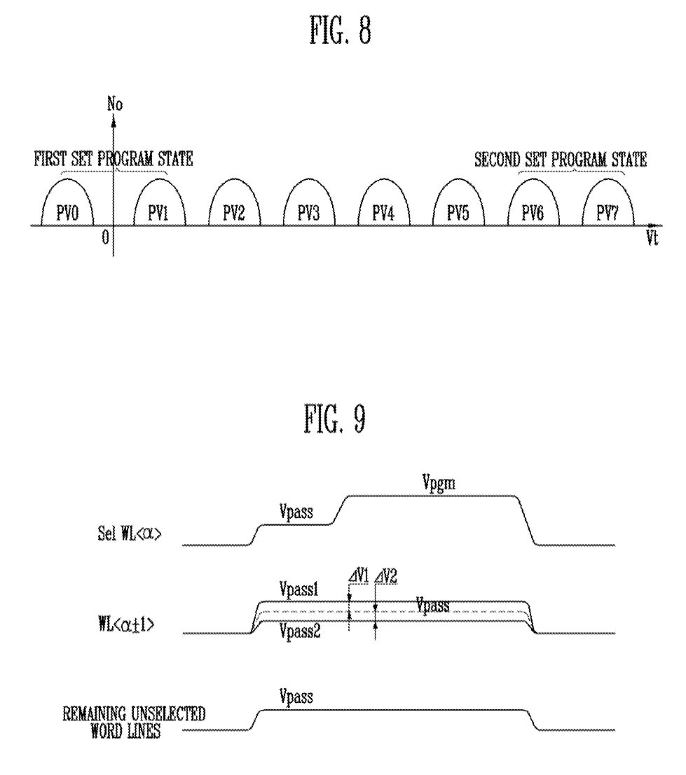

FIG. 9 is a waveform diagram of word line voltages for illustrating operations of a semiconductor memory device according to an embodiment of the present invention.

A method of operating a semiconductor memory device according to an embodiment is described below with reference to FIGS. 1 to 9.

Although a Triple Level Cell (TLC) program method is exemplified by setting first set program states PV0 and PV1 and second set program states PV6 and PV7, the invention is not limited thereto. The first set program states PV0 and PV1 may be defined as one or more program states having a low threshold voltage distribution, and the second set program states PV6 and PV7 may be defined as one or more program states having a high threshold voltage distribution. Embodiments of the present invention may be applied to a Multi-Level Cell (MLC) (i.e., a two-bit cell) or a Quad-Level Cell (QLC) program method in the similar way to the exemplified TLC program method hereafter.

When the command CMD for a program command is input from an external source at step S110, the control logic 140 may control peripheral circuits to perform the program operation to the semiconductor memory device 100. The read and write circuit 130 may temporarily store data the DATA to which are to be programmed and which are also received from the external source together with the program command.

The control logic 140 may set the first voltage adjustment value ΔV1 and the second voltage adjustment value ΔV2 according to an address of a selected one among a plurality of pages included in a selected memory block (e.g., BLK1) at step S120.

As discussed earlier as a channel width of memory cells included in the selected page is narrower, the first voltage adjustment value ΔV1 and the second voltage adjustment value ΔV2 may decrease. As the channel width of the memory cells included in the selected page is wider, the first voltage adjustment value ΔV1 and the second voltage adjustment value ΔV2 may increase. The channel width may vary depending on the location of the selected page, resulting in a different amount of cell current according to the location of the page during a program operation. Therefore, a threshold voltage distribution may differ between each page. In accordance with an embodiment, the control logic 140 may make the amount of cell current substantially uniform or uniform by determining the first and second voltage adjustment values ΔV1 and ΔV2 (i.e., by setting the first and second variable pass voltages Vpass1 and Vpass2) according to the channel width of the memory cells in the selected page, which leads to a substantially uniform or uniform threshold voltage distribution of the memory cells in the selected page during the program operation.

Subsequently, a program operation of the selected page may be performed at step S130.

The program operation will be described below.

The control logic 140 may control the peripheral circuits to perform a program operation on the selected page in a sequential manner from a program operation for a low program state (i.e., a program state having a low threshold voltage distribution) to a high program state (i.e., a program state having a high threshold voltage distribution).

The control logic 140 may set the first variable pass voltage Vpass1 for word lines of a page adjacent to the selected page during a program operation for the first set program states PV0 and PV1 at step S131. The first variable pass voltage Vpass1 may be higher than the pass voltage Vpass by the first voltage adjustment value ΔV1.

Subsequently, a program operation for the program state PV1 may be performed except for an erase state PV0 between the first set program states PV0 and PV1 at step S132. The voltage generator 150 may generate the pass voltage Vpass and the first variable pass voltage Vpass1. The address decoder 120 may apply the pass voltage Vpass to a word line WL<α> of the selected page and the first variable pass voltage Vpass1 to word lines WL<α±1> of adjacent pages to the selected page. In addition, the address decoder 120 may apply the pass voltage Vpass to word lines of the remaining pages. Subsequently, the voltage generator 150 may generate the program voltage Vpgm, and the address decoder 120 may apply the program voltage Vpgm to the word line WL of the selected page to perform the program operation for the program state PV1.

The first set program states PV0 and PV1 have a relatively low threshold voltage distribution, and thus the threshold voltage distribution of the first state set program states may be affected by interference of a program operation to an adjacent page. In accordance with an embodiment a threshold voltage distribution of the program state PV1 may widen through the program operation for the first set program states PV0 and PV1 by applying the first variable pass voltage Vpass1, which is higher than the pass voltage Vpass, to the word line WLadj of the adjacent pages to the selected page. Accordingly, the memory cells having the wide threshold voltage distribution of the program state PV1 may be less affected by interference of a subsequent program operation to the adjacent page, and thus the threshold voltage distribution of the program state PV1 may not be deteriorated.

Subsequently, the control logic 140 may perform a program operation for one or more program states (e.g., the program states PV2 to PV5 shown in FIG. 8) having threshold voltage distributions between the first set program states PV0 and PV1 and the second set program states PV6 and PV7 at step S133. The control logic 140 may control the peripheral circuits to perform the program operation on the selected page in a sequential manner from a low program state (i.e., the program state PV2) to a high program state (i.e., the program state PV5). The pass voltage Vpass may be applied to the word lines WLadj of adjacent pages to the selected page during the program operations for the program states PV2 to PV5 having the threshold voltage distributions between the first set program states PV0 and PV1 and the second set program states PV6 and PV7.

Subsequently, the control logic 140 may set the second variable pass voltage Vpass2 for word lines of a page adjacent to the selected page during a program operation for the second set program states PV6 and PV7 at step S134. The second variable pass voltage Vpass2 may be lower than the pass voltage Vpass by the second voltage adjustment value ΔV2.

Subsequently, program operations may be sequentially performed for the second set program states PV6 and PV7 at step S135. The voltage generator 150 may generate the pass voltage Vpass and the second variable pass voltage Vpass2. The address decoder 120 may apply the pass voltage Vpass to the word line WL of the selected page and the second variable pass voltage Vpass2 to the word lines WLadj of adjacent pages to the selected page. In addition, the address decoder 120 may apply the pass voltage Vpass to word lines of the remaining pages. Subsequently, the voltage generator 150 may generate the program voltage Vpgm, and the address decoder 120 may apply the program voltage Vpgm to the word line WL of the selected page to perform the program operation for the program state PV6. When the program operation for the program state PV6 is completed, the program operation for the program state PV7 may be performed by increasing the program voltage Vpgm.

The second set program states PV6 and PV7 have a relatively high threshold voltage distribution, and thus the threshold voltage distribution of the program states (e.g., the program states PV0 to PV5) having lower threshold voltage distribution than the second set program states PV6 and PV7 may be affected by interference of the program operation for the second set program states PV6 and PV7, which may cause undesirable change of threshold voltage distribution, especially lower threshold voltage distribution than the second set program states PV6 and PV7, of program-completed adjacent page. In accordance with an embodiment, a threshold voltage distribution of the program states PV6 and PV7 may narrow through the program operation for the second set program states PV6 and PV7 by applying the second variable pass voltage Vpass2, which is lower than the pass voltage Vpass, to the word lines WLadj of the adjacent pages to the selected page. Accordingly, the memory cells having the narrow threshold voltage distribution of the program states PV6 and PV7 may cause less interference on memory cells of an adjacent page thereby preventing an undesirable change of threshold voltage distribution of the programmed memory cells included in an adjacent page.

According to the program operation of an embodiment, as a program state is higher, a potential level of the program voltage Vpgm may be increased. In addition, the program operations for the respective program states may depend on the application number of the program voltage Vpgm. On the assumption that the program voltage Vpgm is applied a total of twenty-one times during program operations, the program operations for the respective program states PV1 to PV7 may be performed with each three sequential application times of the program voltage Vpgm. For example, a program operation for the program state PV1 may be performed when the program voltage is applied the first three times (i.e., first to third times), a program operation for the program state PV2 may be performed when the program voltage is applied second three times (i.e., fourth to sixth times), and a program operation for the program state PV3 may be performed when the program voltage is applied third three times (seventh to ninth times).

When the program operation of the selected page is completed, it may be determined whether the selected page is the last page at step S140.

As a result of the determination, if the selected page is the last page, the program operation on the selected memory block may be completed. In addition, as the result of the determination, when the selected page is not the last page, the next page may be selected at step S150 and the process proceeds back to step S120.

As described above, according to an embodiment, a threshold voltage distribution of memory cells included in the selected page and the adjacent page may be improved by controlling a pass voltage applied to a page adjacent to a selected page according to a program state to program.

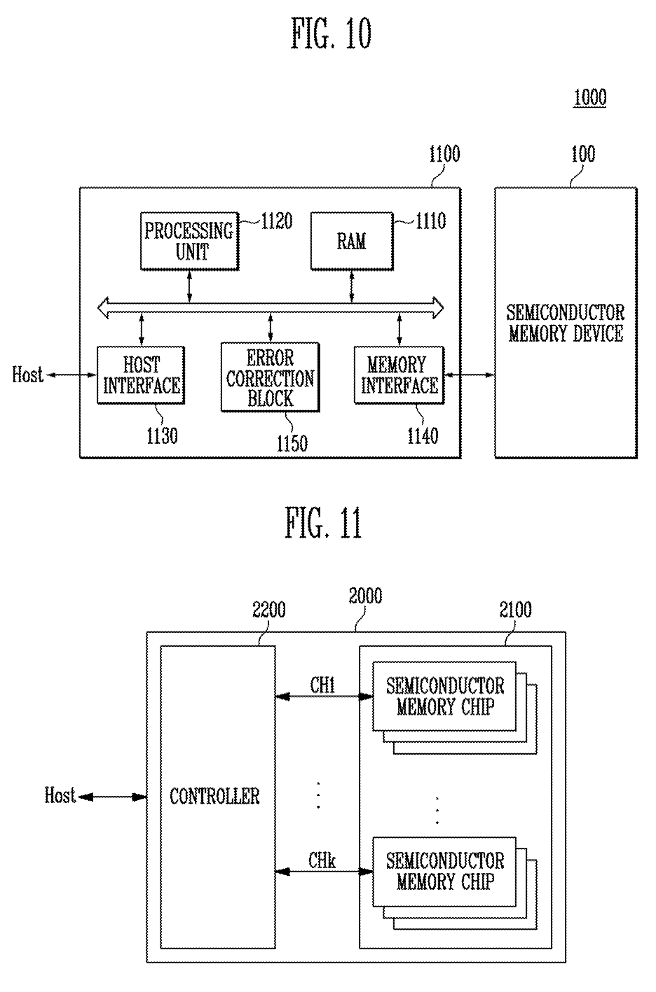

FIG. 10 is a block diagram Illustrating a memory system 1000 according to an embodiment of the present invention.

As illustrated in FIG. 10, the memory system 1000 according to the embodiment may include the semiconductor memory device 100 and a controller 1100.

Since the semiconductor memory device 100 is the same as the semiconductor memory device described above with reference to FIG. 1, a detailed description thereof will be omitted.

The controller 1100 may be operatively coupled to a host and the semiconductor memory device 100 and may access the semiconductor memory device 100 in response to a request received from the host. For example, the controller 1100 may control at least one of a read, write, erase and a background operation of the semiconductor memory device 100. A background operation may be, for example, a bad block management operation, or a garbage collection operation. The controller 1100 may be configured to provide an interface between the semiconductor memory device 100 and the host. The controller 1100 may be configured to drive firmware for controlling the semiconductor memory device 100.

The controller 1100 may include a random access memory (RAM) 1110, a central processing unit (CPU) 1120, a host interface 1130, a memory interface 1140 and an error correction block 1150 operatively coupled via an internal bus. The RAM 1110 may serve as an operation memory of the CPU 1120, a cache memory between the semiconductor memory device 100 and the host, and a buffer memory between the semiconductor memory device 100 and the host. In addition, the controller 1100 may temporarily store program data provided from the host during a read operation.

The host interface 1130 may interface with the host. For example, the controller 1100 may communicate with the host through various interface protocols including a Universal Serial Bus (USB) protocol, a multimedia card (MMC) protocol, a peripheral component interconnection (PCI) protocol, a PCI-express (PCI-E) protocol, an Advanced Technology Attachment (ATA) protocol, a Serial-ATA protocol, a Parallel-ATA protocol, a small computer small interface (SCSI) protocol, an enhanced small disk interface (ESDI) protocol, an Integrated Drive Electronics (IDE) protocol, a private protocol, or a combination thereof.

The memory interface 1140 may interface with the semiconductor memory device 100. For example, the memory interface 1140 may include a NAND interface or a NOR interface.

The error correction block 1150 may detect and correct errors in data read from the semiconductor memory device 100 by using an error correction code (ECC). The processing unit 1120 may control a read voltage based on an error detection result of the error correction block 1150 and perform a re-read operation. According to an embodiment, the error correction block may be provided as a component of the controller 1100.

The controller 1100 and the semiconductor memory device 100 may be integrated in a single semiconductor device. According to an embodiment, the controller 1100 and the semiconductor memory device 100 may be integrated in a single semiconductor device to form a memory card such as a PC card (personal computer memory card international association (PCMCIA)), a compact flash card (CF), a smart media card (SMC), a memory stick, a multimedia card (MMC, RS-MMC or MMCmicro), an SD card (SD, miniSD, micro SD or SDHC), a universal flash storage device (UFS), etc.

The controller 1100 and the semiconductor memory device 100 may be integrated in a single semiconductor device to form a solid state drive (SSD). The SSD may include a storage device for storing data in a semiconductor memory device. When the memory system 1000 is used as an SSD, operational rates of the host coupled to the memory system 1000 may be significantly improved.

In another example, the memory system 1000 may be used as one of several elements in various electronic devices such as a computer, an ultra mobile PC (UMPC), a workstation, a net-book, a personal digital assistant (PDA), a portable computer, a web table, a wireless phone, a mobile phone, a smart phone, an e-book, a portable multimedia player (PMP), a portable game machine, a navigation device, a black box, a digital camera, a three-dimensional television, a digital audio recorder, a digital audio player, a digital picture recorder, a digital picture player, a digital video recorder, a digital video player, a device for transmitting/receiving information in wireless environments, devices for home networks, devices for computer networks, devices for telematics networks, an RFID device, other devices for computing systems, etc.

According to an exemplary embodiment, the semiconductor memory device 100 or the memory system 1000 may be packaged in various forms. For example, the semiconductor memory device 100 or the memory system 1000 may be packaged by various methods such as a package on package (PoP), a ball grid array (BGA), a chip scale package (CSP), a plastic leaded chip carrier (PLCC), a plastic dual in line package (PDIP), a die in waffle pack, a die in wafer form, a chip on board (COB), a ceramic dual in line package (CERDIP), a plastic metric quad flat package (MQFP), a thin quad flat package (TQFP), a small outline integrated circuit (SOIC), a shrink small outline package (SSOP), a thin small outline package (TSOP), a system in package (SIP), a multi chip package (MCP), a wafer-level fabricated package (WFP), a wafer-level processed stack package (WSP), etc.

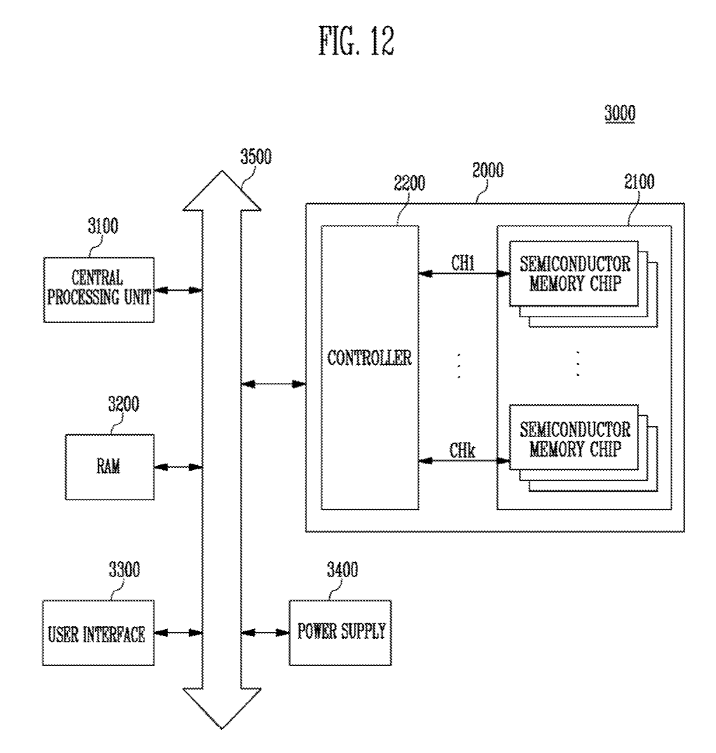

FIG. 11 is a block diagram illustrating an application example (2000) of the memory system 1000 shown in FIG. 10, according to an embodiment of the present invention.

Referring to FIG. 11, a memory system 2000 may include a semiconductor memory device 2100 and a controller 2200. The semiconductor memory device 2100 may include a plurality of semiconductor memory chips 2110. The plurality of semiconductor memory chips may be divided into groups GR1 to GRn.

FIG. 11 illustrates the plurality of groups communicating with the controller 2200 through first to k-th channels CH1 to CHk. Each of the semiconductor memory chips 2110 may be configured and operated in substantially the same manner as one of the semiconductor memory devices 100 described above with reference to FIG. 1.

Each group GR1 to GRn may communicate with the controller 2200 through a single common channel. The controller 2200 may be configured in substantially the same manner as the controller 1100 described with reference to FIG. 10, and configured to control the plurality of semiconductor memory chips 2110 of the semiconductor memory device 2100 through the plurality of first to k-th channels CH1 to CHk.

FIG. 12 is a block diagram Illustrating a computing system 3000 having the memory system described above with reference to FIG. 11, according to an embodiment of the present invention.

Referring to FIG. 12, the computing system 3000 may include a central processing unit 3100, a random access memory (RAM) 3200, a user interface 3300, a power supply 3400, a system bus 3500, and the memory system 2000.

The memory system 2000 may be electrically connected to the central processing unit 3100, the RAM 3200, the user interface 3300 and the power supply 3400 through the system bus 3500. Data provided trough the user interface 3300 or processed by the central processing unit 3100 may be stored in the memory system 2000.

As illustrated in FIG. 12, the semiconductor memory device 2100 may be coupled to the system bus 3500 through the controller 2200. However, the semiconductor memory device 2100 may be directly coupled to the system bus 3500. For example, the central processing unit 3100 and the RAM 3200 may perform the functions of the controller 2200.

As illustrated in FIG. 12, the computing system 3000 may employ the memory system 2000 of FIG. 11. However, in another embodiment, the memory system 2000 may be replaced with the memory system 1000 described above with reference to FIG. 10. According to an embodiment, the computing system 3000 may include both of the memory systems 1000 and 2000 described above with reference to FIGS. 10 and 11, respectively.

According to an embodiment, interference between memory cells may be suppressed by controlling a pass voltage applied to a word line of a page which is adjacent to a selected page during a program operation of a semiconductor memory device, so that a threshold voltage distribution of the memory cells may be improved.

It will be apparent to those skilled in the art that various modifications can be made to the above-described exemplary embodiments of the present invention without departing from the spirit or scope of the invention. Thus, it is intended that the present invention cover all such modifications provided they come within the scope of the appended claims and their equivalents.

What is claimed is:

1. A semiconductor memory device, comprising:
a memory cell array including a plurality of pages;
peripheral circuits suitable for performing a program operation to memory cells included in a selected page of the plurality of pages so that the memory cells have a plurality of program states; and
a control logic suitable for controlling the peripheral circuits to perform the program operation,
wherein the control logic controls the peripheral circuits to apply a first variable pass voltage, which is different from a pass voltage applied to remaining unselected pages, to an adjacent page to the selected page during a program operation for a first set program states having a low threshold voltage distribution among the plurality of program states.

2. The semiconductor memory device of claim 1, wherein the first variable pass voltage has a higher potential level than the pass voltage.

3. The semiconductor memory device of claim 1, wherein the control logic controls the peripheral circuits to apply a second variable pass voltage, which is different from the pass voltage and the first variable pass voltage, to the adjacent page during a program operation for a second set program states having a high threshold voltage distribution among the plurality of program states.

4. The semiconductor memory device of claim 3, wherein the second variable pass voltage has a lower potential level than the pass voltage.

5. The semiconductor memory device of claim 3,
wherein the first set program states include one or more program states having a low threshold voltage distribution, and
wherein the second set program states include one or more program state having a high threshold voltage distribution.

6. The semiconductor memory device of claim 1, wherein the peripheral circuits perform a program operation for the plurality of program states in a sequential manner from a program state having a low threshold voltage distribution to a program state having a high threshold voltage distribution.

7. The semiconductor memory device of claim 1, wherein the control logic adjusts the first and second variable pass voltages to become closer to the pass voltage as a channel width of memory cells included in the selected page becomes narrower.

8. The semiconductor memory device of claim 1, wherein the control logic selects a new page and sets the pass voltage into a new pass voltage according to a position where the new page is arranged when the program operation on the selected page is completed.

9. A semiconductor memory device, comprising:
a memory cell array including a plurality of pages;
peripheral circuits suitable for perform a program operation to memory cells included in a selected page of the plurality of pages so that the memory cells have a plurality of program states; and
a control logic suitable for controlling the peripheral circuit to perform the program operation,
wherein the control logic controls the peripheral circuits to apply a first or second variable pass voltage, which is different from a pass voltage applied to remaining unselected pages, to an adjacent page to the selected page during a program operation for a first set program states having a low threshold voltage distribution among the plurality of program states, or a program operation for a second set program states having a high threshold voltage distribution among the plurality of program states.

10. The semiconductor memory device of claim 9, wherein the first variable pass voltage has a higher potential level than the pass voltage and the second variable pass voltage has a lower potential level than the pass voltage.

11. The semiconductor memory device of claim 9,
wherein the first set program states include one or more program states having a low threshold voltage distribution, and
wherein the second set program states include one or more program states having a threshold voltage distribution.

12. The semiconductor memory device of claim 9, wherein the peripheral circuits perform a program operation for the plurality of program states in a sequential manner from a program state having a low threshold voltage distribution to a program state having a high threshold voltage distribution.

13. The semiconductor memory device of claim 9, wherein the control logic adjusts the first and second variable pass voltages to become closer to the pass voltage as a channel width of memory cells included in the selected page becomes narrower.

14. The semiconductor memory device of claim 9, wherein the control logic selects a new page and sets the pass voltage into a new pass voltage according to a position where the new page is arranged when the program operation on the selected page is completed.

15. A method of operating a semiconductor memory device, the method comprising:
setting a first variable pass voltage to be applied to adjacent pages to a selected page of a plurality of pages;
performing a first program operation for a first set program states having a low threshold voltage distribution among a plurality of program states by applying a program voltage to the selected page, applying the first variable pass voltage to the adjacent pages, and applying a pass voltage to remaining pages; and
performing a second program operation for a next program state having a higher threshold voltage distribution than the first set program states by applying the program voltage to the selected page and applying the pass voltage to unselected pages.

16. The method of claim 15, wherein the first variable pass voltage has a higher potential level than the pass voltage.

17. The method of claim 15, further comprising after the second program:
setting a second variable pass voltage to be applied to the adjacent pages; and
performing a third program operation for a second set program states having a high threshold voltage distribution among the plurality of program states by applying the program voltage to the selected page, applying the second variable pass voltage to the adjacent pages, and applying the pass voltage to the remaining pages.

18. The method of claim 17, wherein the second variable pass voltage has a lower potential level than the pass voltage.

19. The method of claim 15, further comprising, before the setting of the first variable pass voltage, setting first and second voltage adjustment values for the respective first and second variable pass voltages according to an address of the selected page.

20. The method of claim 19, wherein the first variable pass voltage is greater than the pass voltage by the first voltage adjustment value and the second variable pass voltage is lower than the pass voltage by the second voltage adjustment value.
